(19) United States
(12) Patent Application Publication
(10) Pub. No.: US 2016/0237548 A1
(43) Pub. Date: Aug. 18, 2016

(54) PVD COATED POLYCRYSTALLINE DIAMOND AND APPLICATIONS THEREOF

(71) Applicant: Kennametal Inc., Latrobe, PA (US)

(72) Inventors: Fabian ROSENBERGER, Latrobe, PA (US); Armin Josef ZIMMERMANN, Nabburg (DE); Emmanuel EP. PUVILAND, Dambach La Ville (FR)

(21) Appl. No.: 14/620,864

(22) Filed: Feb. 12, 2015

(51) Int. Cl. C23C 14/06; C23C 14/22

(52) U.S. Cl. CPC C23C 14/0605; C23C 14/22

(57) ABSTRACT

In one aspect, cutting tools are described herein employing PCD substrates having coatings applied thereto. A cutting tool, for example, comprises one or more cutting edges including a PCD substrate and a diamond-like carbon coating adhered to the PCD substrate, the diamond-like carbon coating having hardness greater than 4000 HV0.05. In some embodiments, the diamond-like carbon coating has a thickness greater than 0.3 μm and a sp³ fraction of at least 0.85.

### FIELD

The present invention relates to coatings for abrasion resistant polycrystalline materials and, in particular, to the application of diamond-like carbon coatings to polycrystalline diamond (PCD) substrates by physical vapor deposition (PVD).

### BACKGROUND

PCD is an extremely hard and abrasion resistant material rendering it suitable for a variety of wear applications. PCD is generally produced by application of high temperatures and pressures to graphite positioned in large special-purpose presses. Application of such temperatures and pressures converts the hexagonal structure of graphite to the cubic structure of diamond. Metallic solvent and/or catalyst can be employed to reduce temperatures and pressures required for graphite conversion into diamond. For example, cobalt, nickel and/or iron can be included in the synthetic process to ease temperatures and pressures. However, use of such metallic species has disadvantages, as the resulting product comprises diamond grains with metallic binder largely located at grain boundaries.

Metallic binder phase is generally present in an amount of 5-10 vol. % leading to compromises in the chemical and thermal stabilities of the PCD composition. Metallic binder, for example, can enhance graphitization and induce thermal stresses at temperatures in excess of 700° C. due to large disparities in coefficients of thermal expansion between the metallic binder and diamond. Further, PCD cutting inserts are often brazed to less abrasion resistant cutting tool bodies in efforts to control cutting tool fabrication costs. Low temperature braze alloy places additional thermal restrictions on cutting tools as exposure to excessive temperature can severely weaken the braze joint, precipitating tool failure. These thermal constraints can restrict the library of refractory materials that may be successfully applied to PCD substrates of cutting tools, thereby calling for the development of new coating architectures.

### SUMMARY

In one aspect, cutting tools are described herein employing PCD substrates having coatings applied thereto. A cutting tool, for example, comprises one or more cutting edges including a PCD substrate and a diamond-like carbon coating adhered to the PCD substrate, the diamond-like carbon coating having hardness greater than 4000 HV0.05. In some embodiments, the diamond-like carbon coating has a thickness greater than 0.3 μm and a sp³ fraction of at least 0.85.

In another aspect, methods of making cutting tools employing coated PCD substrates are described herein. A method of making a cutting tool comprises providing a PCD substrate of one or more cutting edges of the cutting tool and depositing a diamond-like carbon coating over the PCD substrate by PVD, the diamond-like carbon coating having hardness greater than 4000 HV0.05. In some embodiments, the diamond-like carbon coating is deposited at a temperature of less than about 200° C.

These and other embodiments are described in greater detail in the following detailed description.

### BRIEF DESCRIPTION OF THE DRAWINGS

FIG. 1 is a cross-sectional scanning electron microscopy (SEM) image of a diamond-like carbon coating adhered to a PCD cutting insert surface according to one embodiment described herein.

FIG. 2(a) is a SEM image of a PCD cutting insert brazed to a drill body, the PCD cutting insert comprising a diamond-like carbon coating according to one embodiment described herein.

FIG. 2(b) is a sectional view of the PCD cutting insert of FIG. 2(a) taken at higher magnification.

FIG. 3(a) is a SEM image of an uncoated PCD cutting insert brazed to a drill body.

FIG. 3(b) is a sectional view of the PCD cutting insert of FIG. 3(a) taken at higher magnification.

FIG. 4(a) is a plan view SEM image of a surface of the diamond-like carbon coating applied to the PCD cutting insert of FIG. 2(a).

FIG. 4(b) is a plan view SEM image of an uncoated surface of the PCD cutting insert of FIG. 3(a).

FIGS. 5(a)-(b) illustrate cutting end surfaces of a carbide drill employing coated PCD cutting inserts subsequent to machining aluminum alloy according to some embodiments described herein.

FIG. 5(c) illustrates a cutting end surface of a carbide drill employing uncoated PCD cutting inserts subsequent to machining aluminum alloy.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

Cutting tools are described herein employing PCD substrates having coatings applied thereto. A cutting tool, for example, comprises one or more cutting edges including a PCD substrate and a diamond-like carbon coating adhered to the PCD substrate, the diamond-like carbon coating having hardness greater than 4000 HV0.05.

Turning now to specific components, a PCD substrate of one or more cutting edges of the tool can have any thickness not inconsistent with the objectives of the present invention. In some embodiments, a PCD substrate has a thickness ranging from 0.1 mm to 2 mm. Further, the PCD substrate can have an average grain size of 1 μm to 25 μm. Depending on desired cutting application, the PCD substrate can have a fine grain size of 1-4 μm, a medium grain size of 5-10 μm or a coarse grain size of 25 μm or more.

Moreover, the PCD substrate can exhibit hardness greater than 7000 HV0.05. Vickers hardness values recited herein for the PCD substrate and diamond-like carbon coating are determined according to ASTM E 384, “Standard Method for Knoop and Vickers Hardness of Materials,” ASTM International. In some embodiments, the PCD substrate has hardness of 7500-10,000 HV0.05.

PCD substrates are generally applied to supports to provide cutting inserts for coupling to a tool body. In some embodiments, a PCD substrate is brazed to a support by alloy. Suitable braze alloy can exhibit low melting point of 600 to 750° C. to avoid damage to the PCD substrate. Alternatively, the PCD substrate is sintered to a support. When sintered to a support, the PCD layer can be formed during the sintering process. For example, a support of cemented carbide or ceramic can be placed adjacent to a layer of diamond grains and loaded into a high temperature, high pressure (HPHT) press. During application of HPHT conditions, the diamond grains are sintered to one another to provide the PCD layer adhered to the cemented carbide or ceramic substrate.

Cemented carbide support for a PCD substrate can comprise tungsten carbide (WC). WC can be present in a support in an amount of at least about 80 weight percent or in an amount of at least about 85 weight percent. Additionally, metallic binder of cemented carbide can comprise cobalt or cobalt alloy. Cobalt, for example, can be present in a cemented carbide support in an amount ranging from 1 weight percent to 30 weight percent. In some embodiments, cobalt is present in a cemented carbide support in an amount ranging from 5-15 weight percent or from 6-10 weight percent. Further, a cemented carbide support may exhibit a zone of binder enrichment beginning at and extending inwardly from the surface of the substrate.

Cemented carbide supports can also comprise one or more additives such as, for example, one or more of the following elements and/or their compounds: titanium, niobium, vanadium, tantalum, chromium, zirconium and/or hafnium. In some embodiments, titanium, niobium, vanadium, tantalum, chromium, zirconium and/or hafnium form solid solution carbides with WC of the support. In such embodiments, the substrate can comprise one or more solid solution carbides in an amount ranging from 0.1-5 weight percent. Additionally, a cemented carbide support can comprise nitrogen.

In further embodiments, supports for PCD substrate can include ceramics. Suitable ceramic materials can include silicon nitride, silicon aluminum oxynitride (SiAlON), silicon carbide, silicon carbide whisker containing alumina or mixtures thereof.

As described herein, a diamond-like carbon coating is adhered to the PCD substrate, the diamond-like carbon coating having hardness greater than 4000 HV0.05. The diamond-like carbon coating, in some embodiments, has a value for hardness selected from Table I.

TABLE I
Diamond-like coating hardness (HV 0.05)
≧4500
≧5000
4000-9000
4500-5500

In addition to hardness, the diamond-like carbon coating can have any thickness not inconsistent with the objectives of the present invention. For example, in some embodiments, the diamond-like carbon coating has a thickness of greater than 0.3 μm. Diamond-like carbon coating thickness can also be selected from Table II.

TABLE II
Diamond-like Carbon Coating Thickness

| | |
|---|---|
| ≧0.5 | μm |
| ≧1 | μm |
| 0.3-5 | μm |
| 0.5-3 | μm |
| 1-2 | μm |

In having a structure close to diamond, the coating exhibits a sp³ fraction of at least 0.85 or 0.90. In some embodiments, the diamond-like carbon coating has a sp³ fraction of 0.85 to 0.95. Further, the diamond-like carbon coating can be free of graphite and/or free of cracks. Several commercial sources are available for providing diamond-like coatings described herein under the ta-C coating designation.

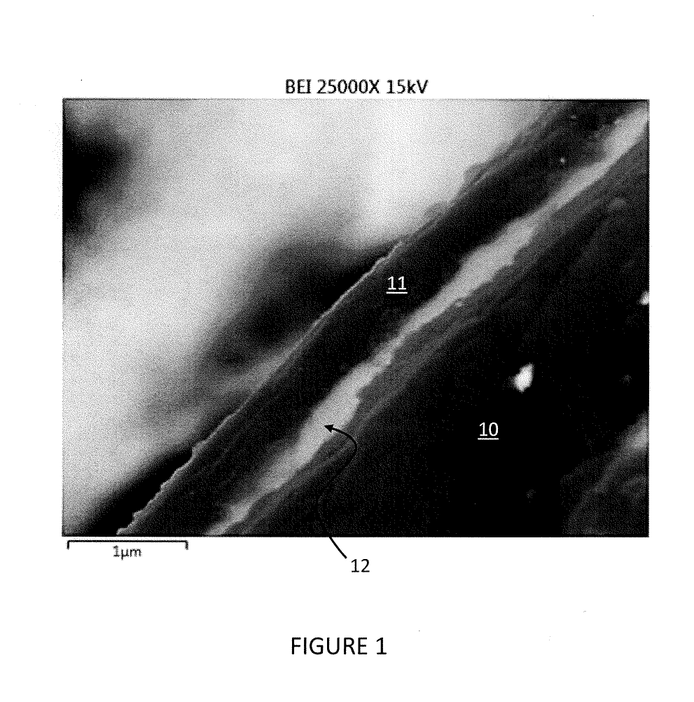

The diamond-like carbon coating can be deposited by one of several PVD techniques including cathodic arc deposition or high power impulse magnetron sputtering. Deposition temperatures are generally less than 250° C. or less than 200° C. In some embodiments, deposition temperature ranges from 80° C. to 150° C. or 100° C. to 200° C. Such low deposition temperatures permit application of the diamond-like carbon coating to the PCD substrate subsequent to brazing of the PCD substrate to a cutting tool body. For example, a cutting insert having a PCD substrate coupled to a support is brazed to a cutting tool body. The PCD substrate is subsequently coated with the diamond-like carbon coating. In such embodiments, the diamond-like carbon coating can also be applied to the support and/or portions of the tool body to which the cutting insert is brazed. Further, the diamond-like carbon coating can be deposited directly on the PCD substrate surface. Alternatively, one or more interlayers may exist between the PCD substrate surface and diamond-like carbon coating. Interlayers can comprise materials for improving adhesion of the diamond-like carbon coating and/or enhancing wear characteristics of the cutting tools. In some embodiments, an interlayer is formed of metal or alloy. In some embodiments, for example, an interlayer comprising chromium is positioned between the PCD substrate and diamond-like carbon coating. FIG. 1 is a cross-sectional SEM image of a diamond-like carbon coating adhered to a PCD cutting insert surface according to one embodiment described herein. As illustrated in FIG. 1, a chromium interlayer (12) binds the diamond-like carbon coating (11) to the PCD substrate (10). In other embodiments, interlayers can comprise one or more refractory materials such as TiN, TiCN, TiC or Al₂O₃. An interlayer can have any thickness not inconsistent with the objectives of the present invention. An interlayer, for example can have a thickness of 0.1 μm to 1 μm or 0.1 to 0.5 μm. In some embodiments, an interlayer has a thickness of at least 50 percent the thickness of the diamond-like carbon coating. In the embodiment illustrated in FIG. 1, the chromium interlayer has a thickness of 0.3-0.5 μm.

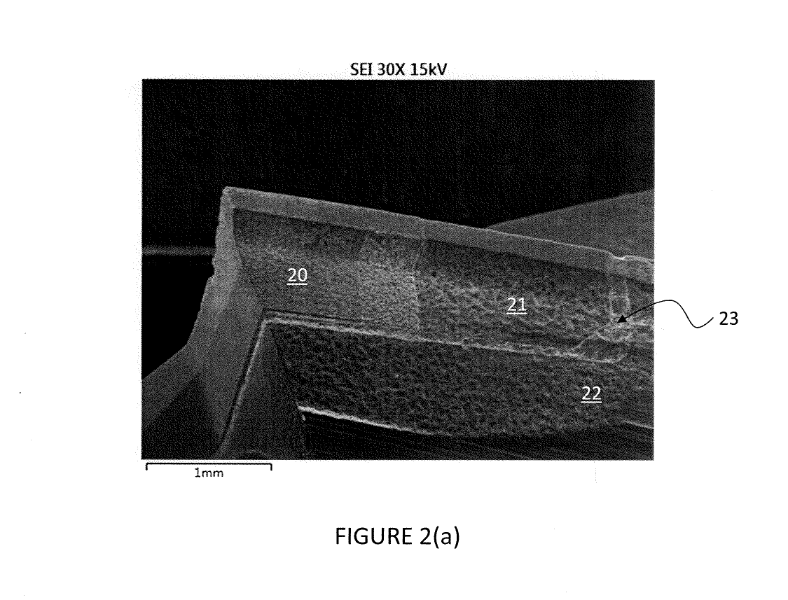

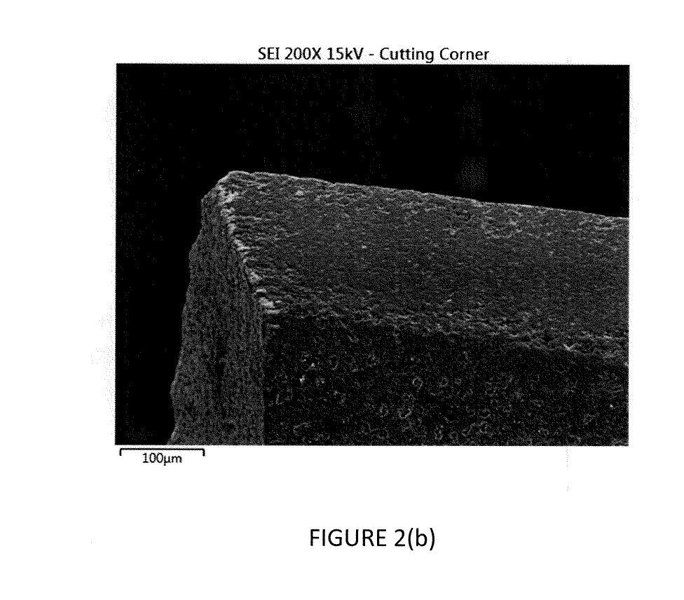

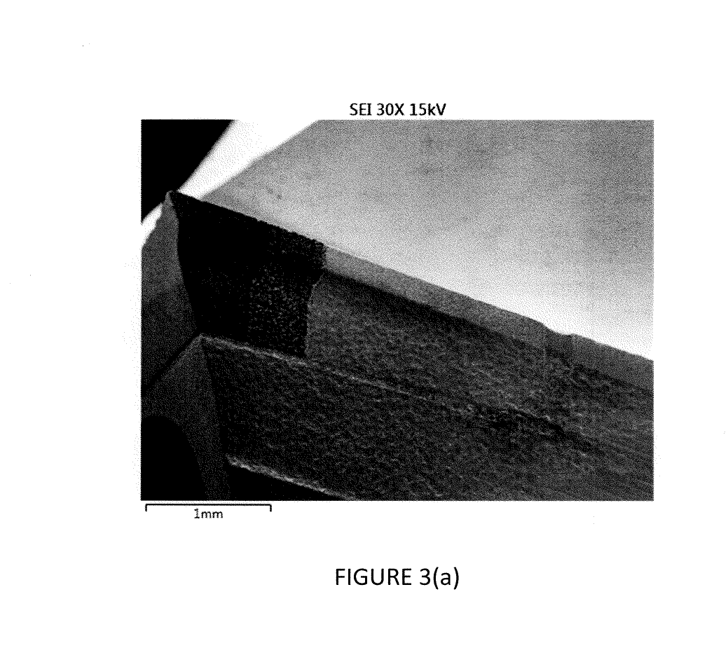

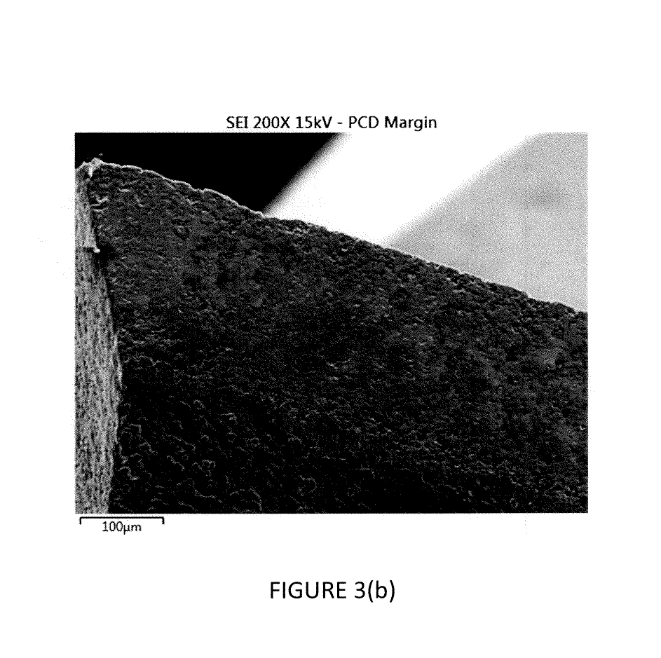

The diamond-like carbon coating can retain cutting edge geometry and sharpness of the PCD substrate. FIG. 2(a) is a SEM image of a PCD cutting insert brazed to a cemented carbide drill body according to one embodiment described herein. The PCD cutting insert comprises a PCD substrate (20) sintered to a cemented carbide support (21). The PCD cutting insert is coupled to the carbide drill body (22) by a braze joint (23). In the embodiment of FIG. 2(a), the PCD substrate (20) and cemented carbide support (21) are coated with a diamond-like carbon coating having thickness of about 0.5 μm. Cutting edge geometry and sharpness of the PCD substrate is not altered by the diamond-like carbon coating. FIG. 2(b) is a SEM of the PCD substrate cutting corner further illustrating retention of cutting edge geometry and sharpness subsequent to application of the diamond-like carbon coating. An uncoated PCD cutting insert of similar construction brazed to a cemented carbide drill body is illustrated in FIGS. 3(a) and 3(b) for comparative purposes.

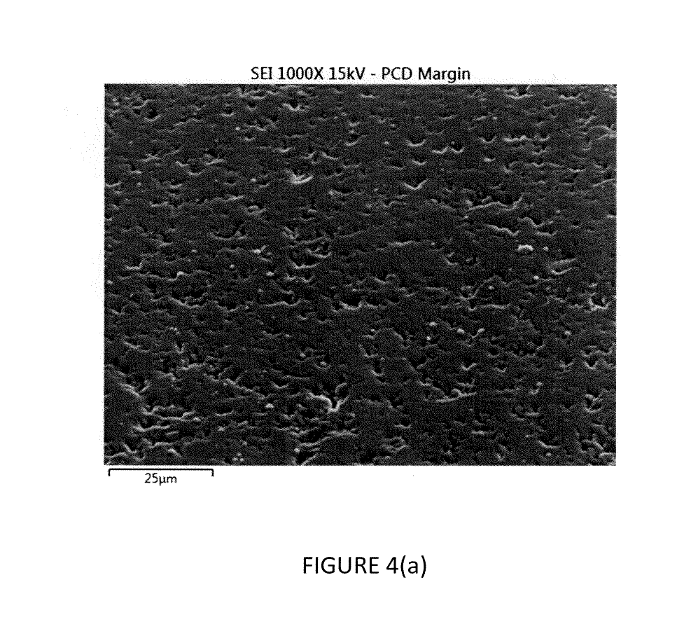

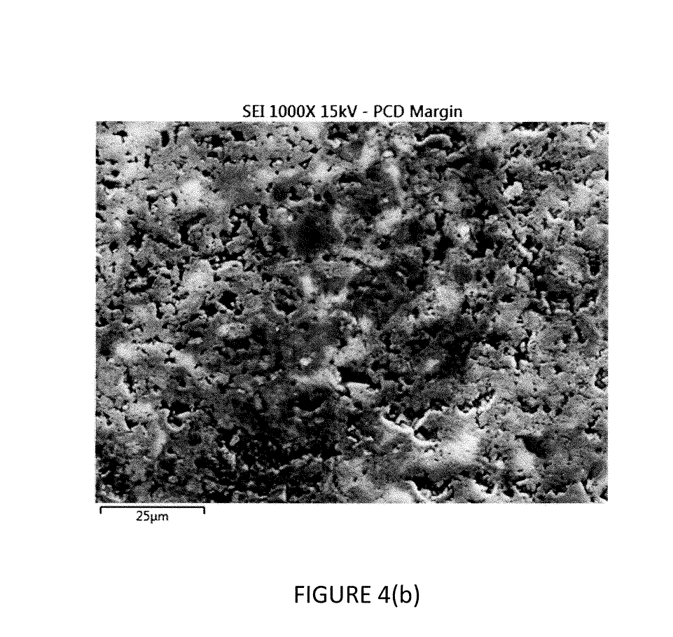

As discussed in the Examples below, the diamond-like carbon coating provides the PCD cutting edge a low coefficient of friction. The low coefficient of friction can enhance chip flow during cutting operations and inhibit material build-up on the cutting edge. FIG. 4(a) is a plan view SEM of a section of the diamond-like carbon coating on the margin of the PCD cutting insert of FIG. 2(a). The microstructure of the diamond-like carbon coating is markedly different than PCD microstructure. For comparative purposes, FIG. 4(b) is a plan view SEM of uncoated PCD on the margin of the cutting insert of FIG. 3(a).

Cutting tools employing one or more cutting edges including a PCD substrate coated with diamond-like carbon can have geometry and architecture for interrupted cut applications. For example, such cutting tools can include end mills and cutting inserts for use in milling applications. In other embodiments, cutting tools described herein include turning inserts. Further, cutting tools described herein can include drills, indexable cutting inserts and cutter bits for earth boring applications and/or roadwork. Cutter bits, for example, can comprise roller cone bits, earth boring bits, percussion bits (impact bits) and drag bits.

The foregoing embodiments are further illustrated by the following non-limiting examples.

### Example 1

### Drill Comprising ta-C Coated PCD Cutting Inserts

A drill comprising PCD cutting inserts brazed to a cemented carbide drill body was provided. The PCD cutting inserts each included a PCD substrate sintered to a cemented carbide support. The brazed PCD cutting inserts were coated with a diamond-like carbon coating (ta-C) having thickness of 0.5 μm and hardness/microstructure described herein. FIGS. 2(a) and (b) discussed above are SEM images of the coated PCD cutting inserts.

The drill employing the brazed and ta-C coated PCD cutting inserts was subjected to metal cutting testing according to the parameters below.

### Drilling Parameters

### Workpiece: Aluminum 6061

### Drill Diameter: 6.345 mm

### Depth of Hole: 22 mm

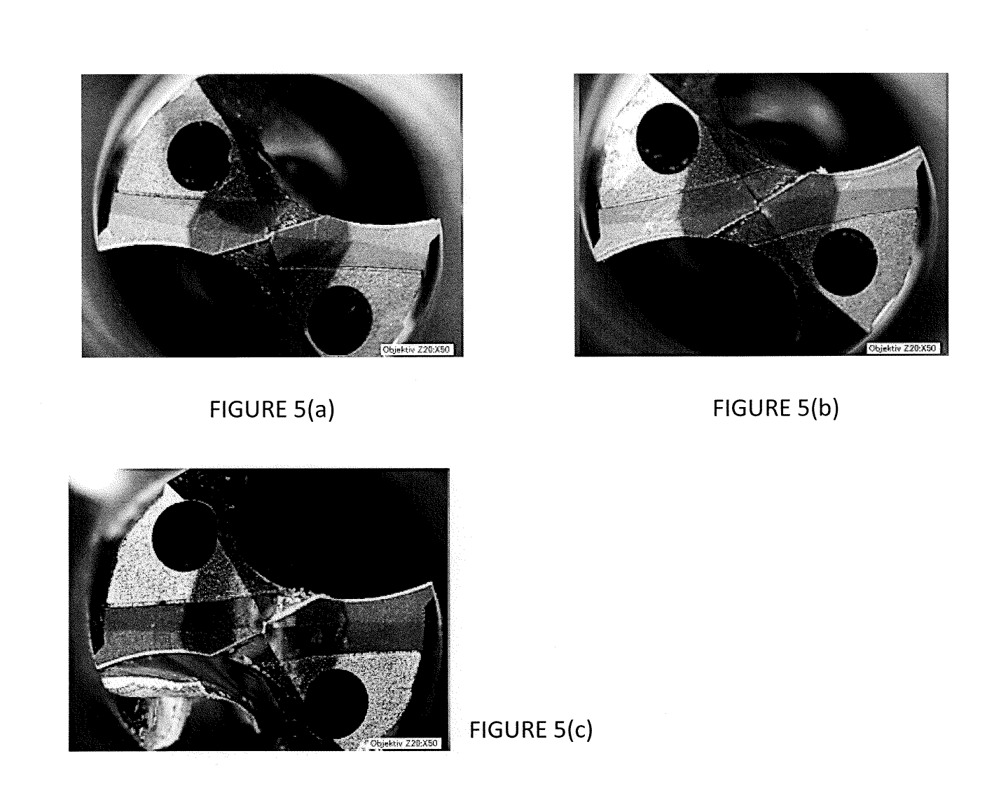

Coolant—Internal emulsion 5%
Feed rate: 0.06 mm/rec
Speed: 150 m/min
10 holes were initially drilled in the Aluminum 6061 workpiece. Examination of the drill cutting end as illustrated in FIG. 5(a) revealed lack of workpiece build-up and reduced wear. The drill was subsequently used to form 160 additional holes in the Aluminum 6061 workpiece and re-examined. As illustrated in FIG. 5(b), cutting edges of the drill maintained lack of workpiece build up and minimal wear.

For comparative purposes, a drill of identical construction less the diamond-like carbon coating (ta-C) was employed to form 9 holes in the Aluminum 6061 workpiece. As illustrated in FIG. 5(c), the uncoated drill exhibited significant workpiece build-up and wear on the cutting end.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. A cutting tool comprising:
one or more cutting edges including a polycrystalline diamond substrate and a diamond-like carbon coating adhered to the polycrystalline diamond substrate, the diamond-like carbon coating having hardness greater than 4000 HV0.05.

2. The cutting tool of claim 1, wherein the diamond-like carbon coating has a thickness greater than 0.3 μm.

3. The cutting tool of claim 1, wherein the diamond-like carbon coating has a thickness of 0.5 μm to 3 μm.

4. The cutting tool of claim 1, wherein the diamond-like carbon coating has a sp³ fraction greater than 0.90.

5. The cutting tool of claim 1, wherein the diamond-like carbon coating has a sp³ fraction of 0.85 to 0.95.

6. The cutting tool of claim 1, wherein the hardness of the diamond-like carbon coating is greater than 5000 HV0.05.

7. The cutting tool of claim 1, wherein the polycrystalline diamond substrate has hardness greater than 7000 HV0.05.

8. The cutting tool of claim 1, wherein the polycrystalline diamond substrate has hardness of 7500 to 10,000 HV0.05.

9. The cutting tool of claim 1, wherein the diamond-like carbon coating is deposited directly on the polycrystalline diamond substrate.

10. The cutting tool of claim 1, wherein a chromium interlayer is positioned between the polycrystalline diamond substrate and the diamond-like carbon coating.

11. The cutting tool of claim 1, wherein the diamond-like carbon coating is deposited by physical vapor deposition.

12. The cutting tool of claim 1, wherein the polycrystalline diamond substrate is brazed or sintered to a support.

13. The cutting tool of claim 12, wherein the support comprises cemented carbide.

14. The cutting tool of claim 12, wherein the diamond-like carbon coating is further adhered to the support.

15. The cutting tool of claim 1, wherein the polycrystalline diamond substrate and diamond-like carbon coating are free of graphite.

16. The cutting tool of claim 1, wherein the diamond-like carbon coating is free of cracks.

17. The cutting tool of claim 1, wherein the cutting tool is an interrupted cut tool.

18. The cutting tool of claim 17, wherein the interrupted cut tool is an end mill or drill.

19. The cutting tool of claim 1, wherein the cutting tool is a turning insert.

20. A method of making a cutting tool comprising:
providing a polycrystalline diamond substrate of one or more cutting edges of the cutting tool and depositing a diamond-like carbon coating over the polycrystalline diamond substrate by physical vapor deposition, the diamond-like carbon coating having hardness greater than 4000 HV0.05.

21. The method of claim 20, wherein the diamond-like carbon coating is deposited at a temperature of less than 200° C.

22. The method of claim 20, wherein the diamond-like carbon coating has a thickness of 0.5 μm to 5 μm.

23. The method of claim 20, wherein the polycrystalline diamond substrate is brazed to a body of the cutting tool prior to deposition of the diamond-like carbon coating.
